(19) United States
(12) Patent Application Publication
(10) Pub. No.: US 2014/0320128 A1
(43) Pub. Date: Oct. 30, 2014

(54) METHOD AND MAGNETIC RESONANCE APPARATUS TO ACQUIRE IMAGE DATA SETS OF AN EXAMINATION SUBJECT

(71) Applicant: Siemens Aktiengesellschaft, Muenchen (DE)

(72) Inventors: Dominik Paul, Bubenreuth (DE); Raphael Schwarz, Erlangen (DE)

(73) Assignee: Siemens Aktiengesellschaft, Muenchen (DE)

(21) Appl. No.: 14/260,618

(22) Filed: Apr. 24, 2014

(30) Foreign Application Priority Data
Apr. 24, 2013 (DE) 102013207438.7

(51) Int. Cl. G01R 33/341

(52) U.S. Cl. CPC G01R 33/341
USPC 324/309; 324/322

(57) ABSTRACT

In a magnetic resonance method and apparatus to image data sets of an examination subject by operation of the magnetic resonance apparatus, after detecting a region of the examination subject that is relevant to the examination, a coil element from each of two coil units is selected depending on the detected region, and acquisition of the image data sets of the examination subject takes place with the use of the selected coil elements. The selection of the coil elements of the coil units can be based on information about a position of a slice of a volume of the examination subject, and the position of the slice can be determined automatically using reference measurements.

### BACKGROUND OF THE INVENTION

1. Field of the Invention

The present invention concerns a method to acquire image data sets of an examination subject by operation of a magnetic resonance (MR) apparatus, as well as an electronically readable data storage medium encoded with programming instructions and a magnetic resonance apparatus, for implementing such a unit head.

2. Description of the Prior Art

Magnetic resonance tomography (MRT) is an imaging modality that enables high-resolution generation of slice images of living organisms (such as humans). The patient is supported in a homogeneous, basic magnetic field B₀. With gradient coils, the external magnetic field is modified in the FOV (field of view) such that a body slice is selected, and a spatial coding of the generated magnetic resonance (MR) signals takes place. In the subsequent reconstruction of the MR signals (via Fourier transformation, for example), an image of the selected slice is created that is used for medical diagnostics. Generation and detection of the MR signals occur with a radio-frequency system that includes a transmission antenna (that radiates radio-frequency (RF) excitation pulses into the patient) and a reception antenna (that detects the emitted RF resonance signals and relays them for image reconstruction). By the selection of a suitable pulse sequence (such as a spin echo sequence or a gradient echo sequence) and the sequence parameters associated therewith, the contrast of the MR images can be varied in numerous ways depending on the diagnostic task. MRT produces images showing structures of the body and accordingly represents a structural imaging method.

Within the MR imaging procedure, body coils (also often called surface coils) are used in order to be able to optimally measure defined regions of the patient's body. To achieve a high signal intensity (and therefore a high image quality), it is advantageous to mold such body coils to conform to the body contour of the patient. For example, head coils are known that have an open shape that surrounds the head, as are spinal column coils that have an oblong shape on which the patient lies, and the like. The body coil can be in one part, but it can also be in multiple parts (predominantly in the case of a head coil).

Body coils are normally of cylindrical design and have multiple coil elements (known as resonator segments) arranged in a distributed manner that normally include at least one capacitive element as well as a conductor element that preferably runs parallel to the longitudinal axis of the surrounding basic field magnet. A conductor segment is often designed as a strip conductor, with multiple conductor segments arranged in a distributed manner around the periphery of the body coil. Coils are known in which the resonator segments are electromagnetically decoupled from one another so that each resonator segment can be controlled separately (individually) via a control device.

Using the body coil, namely the coil elements thereof, for image acquisition a homogeneous, radio-frequency excitation magnetic field is generated inside the body coil (which can be oval in cross section or can be deformed in another way). The radio-frequency excitation magnetic field causes the nuclear spins in the patient to be examined to be deflected from the aligned orientation they have been given by the basic magnetic field.

### SUMMARY OF THE INVENTION

An object of the invention is to provide a method to acquire image data sets of an examination subject by operation of a magnetic resonance apparatus with an optimized use of the coil elements of the body coil.

The invention utilizes the coil elements among multiple coil elements (that are present anyway for a magnetic resonance measurement) of two coil units, together with a suitable detection of the region of an examination subject that is to be examined, in order to ensure an optimized imaging and an optimized workflow with the coil units that are used.

The method according to the invention to acquire image data sets of an examination subject by operation of a magnetic resonance apparatus includes the following steps.

At least one region of the examination subject is detected that is relevant to the examination.

At least one coil element, among multiple coil elements of a first coil unit of the magnetic resonance apparatus, is selected and at least one coil element, among multiple coil elements of a second coil unit of the magnetic resonance apparatus, is also selected, depending on the at least one detected region.

Image data sets of the examination subject are acquired by operation of the magnetic resonance apparatus using the selected coil elements.

By the detection of the relevant examination region, it can be established which coil elements of the respective coil units are relevant to the creation of the image data sets. The coil elements of two coil units can then be selected and used for the acquisition of the image data sets. In this way, special flex coils—coils with multiple coil elements that are movable counter to one another—can be used such that they result in a comfortable support of the examination subject. Thus the method according to the invention offers not only a significantly greater patient comfort, but also significantly better time savings due to the complicated positioning work that is made unnecessary. The use of the method according to the invention is less linked to the experience of a user, and thus is less susceptible to operator errors.

In a preferred embodiment, the first coil unit is a body coil and/or the second coil unit is a back coil. The body coil is simply to be positioned on the patient; it is not necessary to wind and/or arrange the coil around the body of the patient. The back coil is advantageously already integrated within the magnetic resonance apparatus, for example within a bed table of a patient bearing device. Here as well, additional positioning tasks are foregone.

In an embodiment, the positioning of the examination subject takes place between the first coil unit and the second coil unit. For example, a top side and a bottom side of the examination subject are covered at least in part by the coil units. The selection of the suitable coil elements of the coil units is thereby facilitated.

In a further embodiment, the positioning of the examination subject within the magnetic resonance apparatus takes place automatically. For example, the automatic positioning takes place via an automatic control of an insertion movement of the patient table on which the examination subject and the coil units for the pending examination are positioned. The selection of the suitable coil elements of the coil units is also thereby facilitated.

In another embodiment according to the invention, the selection of the coil elements of at least one of the coil units is based on information of a preceding magnetic resonance measurement. For example, such magnetic resonance measurements can, but need not, also include stored data of a preceding measurement. In this way, the region to be examined (and accordingly the relevant coil elements of the coil units) can be determined with greater precision.

In a preferred embodiment, the selection of the coil elements of at least one of the coil units is based on information about a position of at least one slice of a volume of the examination subject. The region to be examined, and accordingly the relevant coil elements of the coil units, thus can also be determined with greater precision.

In another embodiment, the position of the at least one slice is determined using information of a measurement protocol. Such an association of information from the measurement protocol with the slice selection—and ultimately with the selection of the coil elements of at least one of the coil units—facilitates the medical examination for the diagnosis and ultimately leads to a faster creation of the image data sets. The determination of the position using information of a measurement protocol can take place manually, but can also take place automatically.

In a further embodiment, the position of at least one slice is determined automatically using reference measurements. Among other things, such reference measurements can supply the position and orientation of the examination subject and the FOV for the imaging of the relevant regions of the examination subject, and contribute to a more precise imaging.

In another embodiment according to the invention, the selection of the coil elements of at least one of the coil units is dependent on a distance of the coil elements from the relevant region of the examination subject. Further-distant coil elements that degrade the total signal-to-noise ratio can thus be excluded from the imaging process. In a preferred embodiment, this distance is the shortest distance.

In an embodiment, the selection of the coil elements of at least one of the coil units takes place automatically in a computerized processor. Since the manner that the selection of the coil elements should take place can be established using various criteria (for instance the distance of the coil elements from the relevant region of the examination subject), this process can also be automated by these criteria being implemented in a detection unit of the magnetic resonance apparatus, for example. This can shorten the measurement time and reduce the tendency toward error due to user inputs.

In preferred embodiments, the examination subject is a patient and the relevant region of the patient encompasses the torso of the patient, at least in part. Primarily (but not exclusively) given unilateral hip examinations, the method according to the invention represents a particular comfort to the patient. Single-side wrapping of the examination subject with flex coils can be avoided without needing to forego coil elements of the coil units near to the patient. The positioning times are shortened, the error rate and user dependency are reduced, the reproducibility of a measurement is improved, and the artifacts in the image reconstruction are reduced. In one exemplary embodiment, the repositioning of the body coils is also done away with in the case of the unilateral hip examination of the other hip of the patient, or given a combined unilateral/bilateral hip examination.

The present invention also encompasses a magnetic resonance apparatus to acquire image data sets of an examination subject. The magnetic resonance apparatus has an MR data acquisition unit; a processing unit; a control device; and an output unit, and is designed to operate as follows.

The acquisition unit is operated to detect at least one region of the examination subject that is relevant to the examination.

At least one coil element, among multiple coil elements of a first coil unit of the magnetic resonance apparatus, is selected dependent on the detected region. At least one coil element, among multiple coil elements of a second coil unit of the magnetic resonance apparatus, is also selected dependent on the at least one detected region. The selection of these coil elements is implemented by the processing unit. The magnetic resonance apparatus is then operated to acquire magnetic resonance image data from the subject, using the selected coil elements.

The present invention also encompasses a non-transitory, computer-readable storage medium encoded with programming instructions that can be loaded into a memory of a programmable controller or computer of a magnetic resonance apparatus. The programming instructions cause all or various embodiments of the method according to the invention as are described above to be executed by the controller or control device of the magnetic resonance apparatus. The programming instructions may require other components (for example libraries and components for performing auxiliary functions) in order to realize the corresponding embodiments of the method. The programming instructions can be in source code that must still be compiled and linked or that only needs to be interpreted, or in an executable software code that need only be loaded into the corresponding computer for execution.

The computer-readable storage medium can be a DVD, a magnetic tape or a USB stick, for example on which is stored electronically readable control information, in particular software.

The advantages of the magnetic resonance apparatus according to the invention and the computer-readable storage medium according to the invention essentially correspond to the advantages of the method according to the invention, as described above. Features, the alternative embodiments that have been mentioned are likewise applicable to the apparatus and storage medium. The corresponding functional features of the method can be implemented by substantive modules, in particular via hardware modules.

### BRIEF DESCRIPTION OF THE DRAWINGS

FIG. 1 is a schematic depiction of a magnetic resonance apparatus according to the invention.

FIG. 2 illustrates an examination subject and two coil units.

FIG. 3 illustrates an examination subject, two coil units and selected coil elements.

FIG. 4 is a flow chart of an embodiment of the method according to the invention.

### DESCRIPTION OF THE PREFERRED EMBODIMENTS

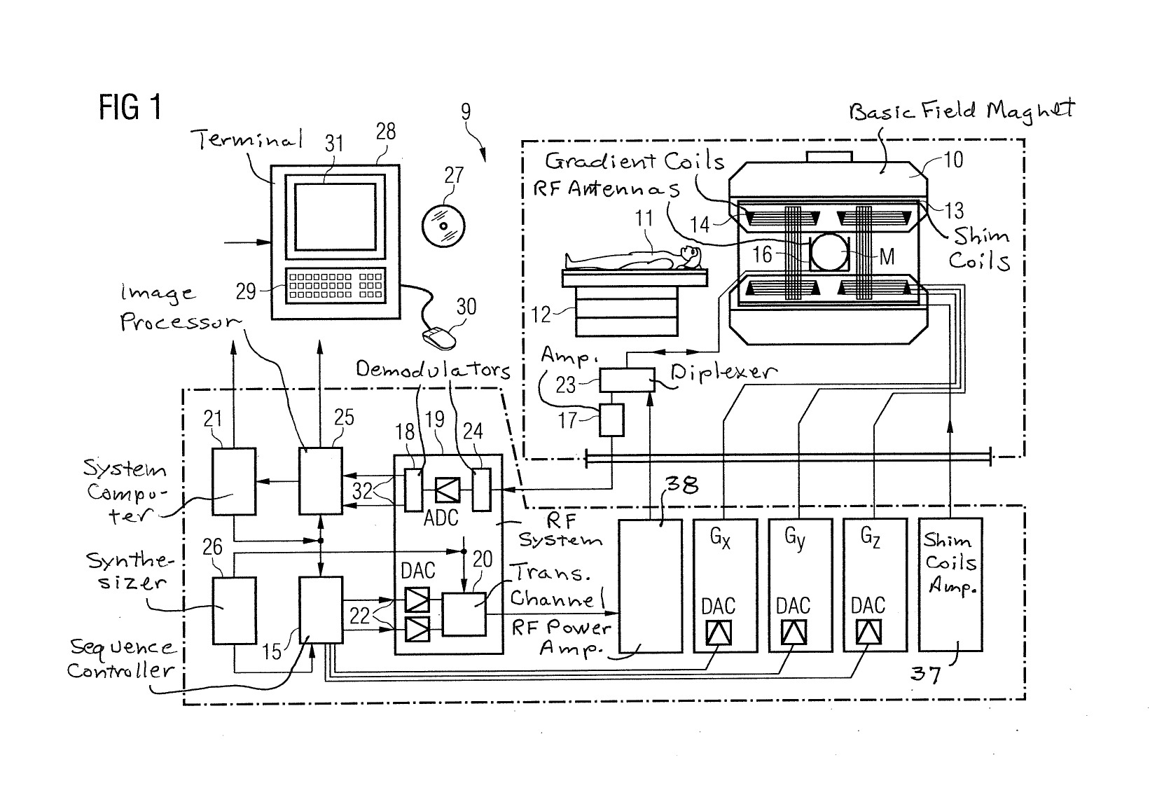

FIG. 1 is a schematic depiction of a magnetic resonance apparatus 9 (a magnetic resonance imaging or magnetic resonance tomography apparatus). A basic field magnet 10 of the magnetic resonance apparatus 9 generates a temporally constant, strong basic magnetic field for polarization or alignment of the nuclear spins in an examination region of an examination subject 11 (for example of a part of a human body that is to be examined) who, lying on a table 12, is moved into the magnetic resonance system 9 for examination. The high homogeneity of the basic magnetic field that is required for the magnetic resonance measurement is defined in a (typically spherical) measurement volume M into which the parts of the human body that are to be examined are moved. To support the homogeneity requirements, and in particular to eliminate temporally invariable influences, shim plates made of ferromagnetic material are mounted at a suitable location. Temporally variable influences, if not wanted, are eliminated by shim coils 13 operated by a shim coils amplifier 37. These are also used in the generation of nonlinear gradients.

In the basic field magnet 10, a cylindrical gradient coil system 14 of the magnetic resonance apparatus 9 is used that has three sub-windings. Each sub-winding is supplied by a respective amplifier of the magnetic resonance apparatus 9 with current to generate a linear (also temporally variable) gradient field in the respective direction of the Cartesian coordinate system. The first sub-winding of the gradient field system 14 generates a gradient Gₓ in the x-direction; the second sub-winding generates a gradient G_{y} in the y-direction; and the third sub-winding generates a gradient G_{z} in the z-direction. Furthermore, the nonlinear gradients are also generated by the gradient field system 14. Each gradient amplifier includes a digital/analog converter DAC, which is controlled by a sequence controller 15 for accurately-timed generation of gradient pulses.

Situated within the gradient field system 14 is at least one radio-frequency antenna 16, which converts the radio-frequency pulses emitted by a radio-frequency power amplifier 38 of the magnetic resonance apparatus 9 into an alternating magnetic field for excitation of the nuclei and alignment of the nuclear spins of the examination subject 11 to be examined, or of the region of the examination subject 11 that is to be examined. Each radio-frequency antenna 16 includes multiple RF transmission coils and multiple RF reception coils or RF reception antennas in the form of an annular (advantageously linear or matrix-like) arrangement of component coils. The alternating field emanating from the precessing nuclear spins—i.e. normally the nuclear spin echo signals caused by a pulse sequence composed of one or more radio-frequency pulses and one or more gradient pulses—is also converted by the RF reception coils of the respective radio-frequency antenna 16 into a voltage (measurement signal) which is supplied via an amplifier 17 to a radio-frequency reception channel 18 of a radio-frequency system 19. The radio-frequency system 19 furthermore has a transmission channel 20 in which the radio-frequency pulses are generated for the excitation of magnetic resonance. The respective radio-frequency pulses are digitally represented in the sequence controller 15 as a series of complex numbers based on a pulse sequence predetermined by the apparatus computer 21 of the magnetic resonance apparatus 9. This number sequence is supplied as a real part and imaginary part to a digital/analog converter DAC in the radio-frequency system 19 via respective inputs 22, and from said digital/analog converter to a transmission channel 20. In the transmission channel 20, the pulse sequences are modulated on a radio-frequency carrier signal having a base frequency that corresponds to the resonance frequency of the nuclear spins in the measurement volume.

The switching from transmission operation to reception operation takes place via a transmission/reception diplexer 23 of the magnetic resonance apparatus 9. The RF transmission coils of the radio-frequency antenna 16 radiate the radio-frequency pulses for excitation of the nuclear spins into the measurement volume M, and resulting echo signals are detected by the RF reception coils. The acquired magnetic resonance signals are phase-sensitively demodulated to an intermediate frequency in a reception channel 24 (the first demodulator of the radio-frequency system 19) and digitized in an analog/digital converter ADC. This signal is further demodulated to a frequency of zero. The demodulation to a frequency of zero, and the separation into real part and imaginary part, occur in a second demodulator 18 (which is connected with the output 32) in the digital domain after the digitization.

An MR image is reconstructed by an image computer 25 of the magnetic resonance apparatus 9 from the measurement data acquired in such a manner. The administration of the measurement data, the image data and the control programs takes place via a system computer or detection unit 21 of the magnetic resonance apparatus 9. Based on a specification with control programs, the sequence controller 15 monitors the generation of the respective desired pulse sequences and the corresponding scanning of k-space. In particular, the sequence controller 15 controls the time-accurate switching of the gradients, the emission of the radio-frequency pulses with defined phase amplitude and the reception of the nuclear magnetic resonance signals. The time base for the radio-frequency system 19 and the sequence controller 15 is provided by a synthesizer 26. The selection of corresponding control programs to generate an MR image (which control programs are stored on a DVD 27, for example), and the presentation of the generated MR image, take place via a terminal or a (processing unit) 28 of the magnetic resonance apparatus 9, which has a keyboard 29, a mouse 30 and an output unit (here a monitor 31).

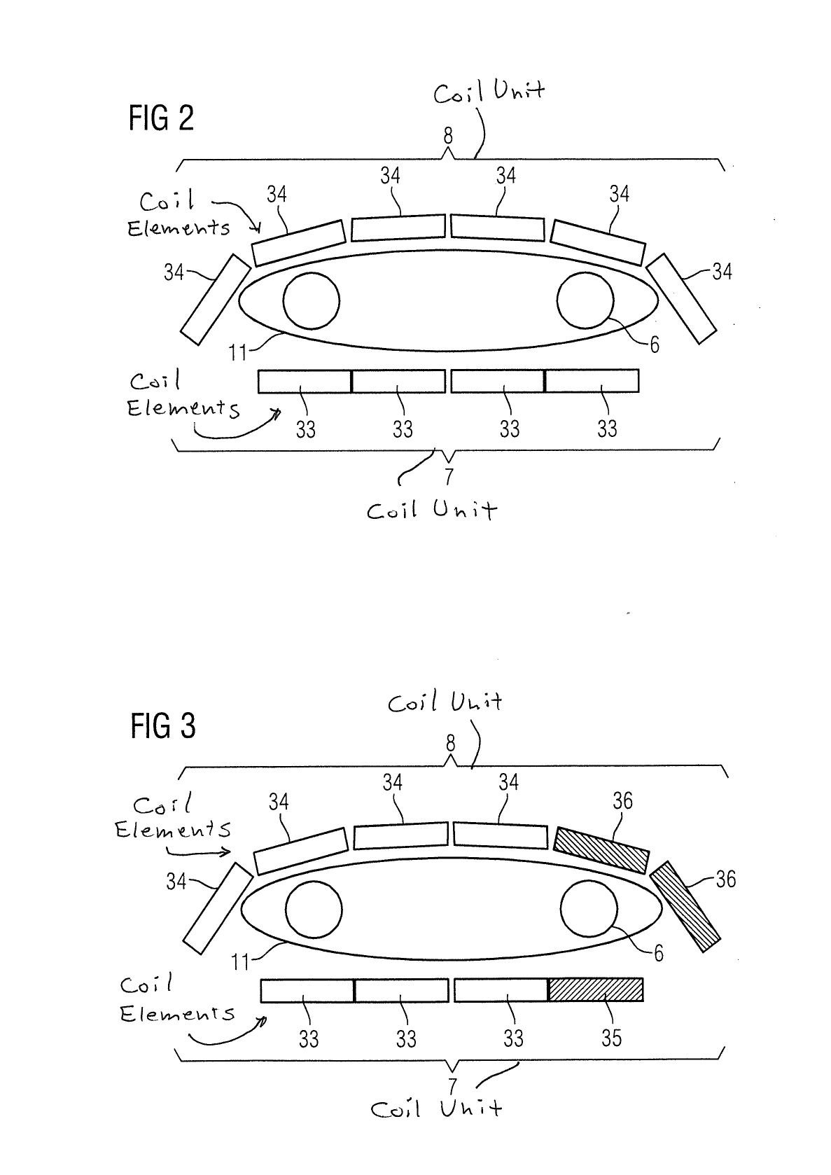

FIG. 2 shows the examination subject 11 and two coil units 7, 8 of the detection unit 21. The examination subject 11—and the relevant region 6 of the examination subject 11 that is to be examined—is positioned between the first coil unit 7 and the second coil unit 8, i.e.—in the present exemplary embodiment—the examination subject 11 is covered at least partially by the coil units 7, 8 from at least two sides. The coil units 7, 8 are respective formed by multiple coil elements 33, 34.

FIG. 3 shows an examination subject 11, two coil units 7, 8 and selected coil elements 35, 36. After the relevant region 6 of the examination subject 11 that is to be examined has been detected (and thus identified), a selection 3 of coil elements 33, 34 of the coil units 7, 8 can take place by means of the processing unit 28 of the magnetic resonance apparatus 9, which serves to create 4 the image data set of the relevant region 6 to be examined by means of the output unit 31 of the magnetic resonance apparatus 9. The selected coil elements 35, 36 thus represent a subset of all possible coil elements 33, 34.

For example, it is thus possible for the selection 3 of the coil elements 33, 34 of at least one of the coil units 7, 8 to be based on information of a preceding magnetic resonance measurement by means of the magnetic resonance apparatus 9, or on information about a position of at least one slice of a volume of the examination subject 11. The position of the slice can, in turn, be determined automatically using a measurement protocol or via reference measurements by means of the magnetic resonance apparatus 9. Among other things, such reference measurements can supply the position and orientation of the examination subject 11 and the FOV for the imaging of the relevant regions 6 of the examination subject 11, and contribute to a more precise imaging.

Reference measurements can be scout scans preceding the actual imaging, i.e. scans that serve for identification of anatomical landmarks; however, they can also be present as stored data sets in databases.

However, the selection 3 of the coil elements 33, 34 of at least one of the coil units 7, 8 can also be dependent on the distance of the coil elements 33, 34 from the relevant region 6 of the examination subject 11. All processes can also be automated in order to accelerate the process of the imaging.

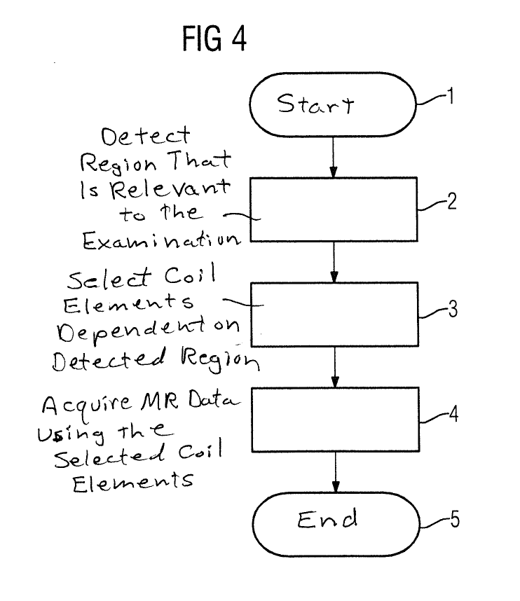

FIG. 4 shows a flow diagram of a method according to the invention. The method includes the method steps 1 through 5, wherein portions of the description—including the corresponding reference characters introduced in connection with other figures—are also used in the description of method steps 1 through 5.

The creation of image data sets of an examination subject by means of a magnetic resonance apparatus is started in method step 1, and during method step 2 at least one region of the examination subject that is relevant to the examination is detected.

In the method step 3, at least one coil element 33 of a first coil unit 7 of the magnetic resonance apparatus 9 and at least one coil element 34 of a second coil unit 8 of the magnetic resonance apparatus 9 are selected depending on the at least one detected region. The first coil unit 7 can be a body coil and/or the second coil unit 8 can be a back (spinal) coil and/or the positioning of the examination subject 11 can take place between the first coil unit 7 and the second coil unit 8. The positioning of the examination subject 11 within the magnetic resonance apparatus 9 can also take place automatically. The selection 3 of the coil elements 33, 34 of at least one of the coil units 7, 8 can also be based on information of a preceding magnetic resonance measurement and/or on information about a position of at least one slice of a volume of the examination subject 11. The position of the at least one slice can be determined automatically using information of a measurement protocol or using reference measurements. The selection 3 of the coil elements 33, 34 of at least one of the coil units 7, 8 can also be dependent on a distance of the coil elements 33, 34 from the relevant region 6 of the examination subject 11. The distance can be the shortest distance. Furthermore, the selection 3 of the coil elements 33, 34 of at least one of the coil units 7, 8 can also take place automatically by the processing unit 28. The examination subject 11 can be a patient, wherein the relevant region 6 of the patient 11 can at least partially include the torso of the patient 11.

MR data are acquired from the examination subject 11 by operating the MR apparatus 9 in a data acquisition sequence using the selected coils of the respective coil units 7, 8.

Method step 5 indicates the end of the image data set creation.

In summary, the invention concerns a method, a magnetic resonance apparatus, and a computer-readable storage medium for the acquisition of image data sets of an examination subject by operation of the magnetic resonance apparatus. After a detection of a region of the examination subject that is relevant to the examination, and the selection of coil elements of coil units depending on the detected region, the acquisition of the image data sets of the examination subject takes place with the use of the selected coil elements. In a preferred embodiment, the selection of the coil elements of the coil units is based on information about a position of a slice of a volume of the examination subject, and the position of the slice is determined automatically using reference measurements.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method to acquire magnetic resonance (MR) image data sets from an examination subject situated in a magnetic resonance apparatus comprising a first coil unit comprising multiple first coil unit elements, and a second coil unit comprising multiple second coil unit elements, said method comprising:
operating the magnetic resonance apparatus to detect at least one region of the examination subject that is relevant to an examination;
selecting at least one first coil unit element from among said multiple first coil unit elements of said first coil unit dependent on said at least one detected region;
selecting at least one second coil unit element, among said multiple second coil unit elements of said second coil unit, dependent on said at least one detected region; and
operating said MR apparatus to acquire at least one MR image data set of the examination subject using said at least one first coil unit element selected from said first coil unit and said at least one second coil unit element selected from said second coil unit.

2. A method as claimed in claim 1 comprising positioning the examination subject between said first coil unit and said second coil unit in said MR apparatus.

3. A method as claimed in claim 2 comprising automatically positioning the examination subject in said magnetic resonance apparatus.

4. A method as claimed in claim 1 comprising detecting said at least one region of the examination subject by executing a magnetic resonance data acquisition procedure in said magnetic resonance apparatus.

5. A method as claimed in claim 1 comprising selecting at least one of said at least one first coil unit element or said at least one second coil unit element based on information describing a position of at least one slice of a volume of the examination subject.

6. A method as claimed in claim 5 comprising determining said position of said at least one slice using information from a measurement protocol used to detect said at least one region of the examination subject.

7. A method as claimed in claim 6 comprising determining said position of said at least one slice using reference measurements relative to the examination subject.

8. A method as claimed in claim 1 comprising selecting said at least one of said first coil unit elements and said at least one of said second coil unit elements dependent on respective distances of the respective multiple first coil unit elements from said relevant region of the examination subject and a distance of the respective multiple second coil unit elements from the relevant region of the examination subject.

9. A method as claimed in claim 8 comprising selecting said at least one first coil unit element as the first coil unit element having a shortest distance from said relevant region of the examination subject, and selecting said at least one second coil unit element as the second coil unit element having a shortest distance from said relevant region of the examination subject.

10. A method as claimed in claim 1 comprising implementing said selection of said at least one first coil unit element and said selection of said at least one second coil unit element automatically in a computerized processor.

11. A method as claimed in claim 1 comprising detecting the torso of the examination subject as said at least one region relevant to the examination.

12. A magnetic resonance apparatus comprising:
a magnetic resonance data acquisition unit comprising a first coil unit comprising multiple first coil unit elements, and a second coil unit comprising multiple second coil unit elements;
a control unit configured to operate the magnetic resonance apparatus to detect at least one region of the examination subject that is relevant to an examination;
said control unit being configured to select at least one first coil unit element from among said multiple first coil unit elements of said first coil unit dependent on said at least one detected region;
said control unit being configured to select at least one second coil unit element, among said multiple second coil unit elements of said second coil unit, dependent on said at least one detected region; and
said control unit being configured to operate said MR apparatus to acquire at least one MR image data set of the examination subject using said at least one first coil unit element selected from said first coil unit and said at least one second coil unit element selected from said second coil unit.

13. A magnetic resonance apparatus as claimed in claim 12 wherein said first coil unit is a body coil.

14. A magnetic resonance apparatus as claimed in claim 12 wherein said second coil unit is a back coil.

15. A non-transitory, computer-readable data storage medium included with programming instructions, said storage medium being loaded into a computerized processor of a magnetic resonance apparatus that comprises a first coil unit, comprising multiple first coil unit elements, and a second coil unit, comprising multiple second coil unit elements, said programming instructions causing said computerized processor to:
operate the magnetic resonance apparatus to detect at least one region of the examination subject that is relevant to an examination;
select at least one first coil unit element from among said multiple first coil unit elements of said first coil unit dependent on said at least one detected region;
select at least one second coil unit element, among said multiple second coil unit elements of said second coil unit, dependent on said at least one detected region; and
operate said MR apparatus to acquire at least one MR image data set of the examination subject using said at least one first coil unit element selected from said first coil unit and said at least one second coil unit element selected from said second coil unit.
